(19) United States
(12) Patent Application Publication
(10) Pub. No.: US 2017/0357558 A1
(43) Pub. Date: Dec. 14, 2017

(54) APPARATUS AND METHOD TO ENABLE A CORRECTED PROGRAM TO TAKE OVER DATA USED BEFORE CORRECTION THEREOF

(71) Applicant: FUJITSU LIMITED, Kawasaki-shi (JP)

(72) Inventor: Takeharu KATO, Kawasaki (JP)

(73) Assignee: FUJITSU LIMITED, Kawasaki-shi (JP)

(21) Appl. No.: 15/616,165

(22) Filed: Jun. 7, 2017

(30) Foreign Application Priority Data
Jun. 13, 2016 (JP) 2016-116857

(51) Int. Cl. G06F 11/16; G06F 11/08; G11C 29/44; G11C 29/00; G06F 9/30

(52) U.S. Cl. CPC G06F 11/1666; G11C 29/84; G06F 9/3004; G11C 29/4401; G06F 11/08

(57) ABSTRACT

An apparatus causes a program loader to load a first program and a second program that is obtained by correcting the first program, into a memory, and causes a linker to load a library used for execution of the second program into the memory. The apparatus writes first data that has been processed at a suspension time at which execution of the first program is suspended, into a first data area for the first program loaded into the memory, and starts execution of the second program from a second position on the second program corresponding to a first position where execution of the first program is suspended.

### CROSS-REFERENCE TO RELATED APPLICATION

This application is based upon and claims the benefit of priority of the prior Japanese Patent Application No. 2016-116857, filed on Jun. 13, 2016, the entire contents of which are incorporated herein by reference.

### FIELD

The embodiments discussed herein are related to apparatus and method to enable a corrected program to take over data used before correction thereof.

### BACKGROUND

Various types of software are utilized by using a computer including a memory and a processor. When executing a software program, the computer loads an executable program (or may be referred to as an execution binary) stored in a secondary storage device (such as a hard disk drive (HDD)) into a memory. The computer executes the program loaded into the memory and exhibits a given function. In this connection, various methods have been devised for efficiently executing the program.

For example, there is a proposal of reducing data amount of the execution binary image by causing a computer to detect an unused area in the execution binary from address solution information of the execution binary and delete the area when loading the execution binary.

Further, there is also a proposal of causing a process management system to prepare in advance a storage area for storing data used for re-execution of the processing as of crash, and re-execute the processing when the crash is not caused by data, and initialize data used in the processing when the crash is caused by data.

Further, there is also a proposal of causing a computer to define two or more execution phases in a program, prepare in advance data to be restored for each of execution phases, and restart execution of the program from a halfway phase by re-reading or resetting data depending on the restarted execution phase.

Also, there is a proposal of implementing high speed start-up of a computer system by starting the system from a primary memory image pre-stored in a nonvolatile storage unit which is a part of a main memory device.

Related techniques are disclosed in, for example, International Publication Pamphlet No. WO 2007/026484, Japanese Laid-open Patent Publication Nos. 2006-65440 and 2005-10897, and Japanese National Publication of International Patent Application No. 2014-509012.

### SUMMARY

According to an aspect of the invention, an apparatus causes a program loader to load a first program and a second program that is obtained by correcting the first program, into a memory, and causes a linker to load a library used for execution of the second program into the memory. The apparatus writes first data that has been processed at a suspension time at which execution of the first program is suspended, into a first data area for the first program loaded into the memory, and starts execution of the second program from a second position on the second program corresponding to a first position where execution of the first program is suspended.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a diagram illustrating an example of an information processing apparatus, according to an embodiment;

FIG. 2 is a diagram illustrating an example of a hardware configuration of a server, according to an embodiment;

FIG. 3 is a diagram illustrating an example of software of a server, according to an embodiment;

FIG. 4 is a diagram illustrating an example of generation of an execution binary, according to an embodiment;

FIG. 5 is a diagram illustrating an example of information added to a global offset table (GOT), according to an embodiment;

FIG. 6 is a diagram illustrating an example of a GOT, according to an embodiment;

FIG. 7 is a diagram illustrating an example of information stored in a storage unit, according to an embodiment;

FIG. 8 is a diagram illustrating an example of an operational flowchart for program loader processing, according to an embodiment;

FIG. 9 is a diagram illustrating an example of an operational flowchart for application initialization processing, according to an embodiment;

FIG. 10 is a diagram illustrating an example of an operational flowchart for dynamic linker initialization processing, according to an embodiment;

FIG. 11 is a diagram illustrating an example of an operational flowchart for dynamic linker initialization processing (continued), according to an embodiment;

FIG. 12 is a diagram illustrating an example of an operational flowchart for execution image recording processing, according to an embodiment;

FIG. 13 is a diagram illustrating an example of offset updating of a GOT, according to an embodiment;

FIG. 14 is a diagram illustrating an example of data access by a post-correction program, according to an embodiment;

FIG. 15 is a diagram illustrating a comparison example of program execution images;

FIG. 16 is a diagram illustrating an example of an operational flowchart for dynamic linker initialization processing, according to an embodiment;

FIG. 17 is a diagram illustrating an example of an unmapped data area, according to an embodiment;

FIG. 18 is a diagram illustrating an example of an operational flowchart for execution image recording processing, according to an embodiment; and

FIG. 19 is a diagram illustrating an example of data access by a corrected program, according to an embodiment.

### DESCRIPTION OF EMBODIMENTS

In operation of a computer, a program is sometimes modified or corrected due to a program error found during execution thereof. To correct the program, execution of a pre-correction program is suspended, and processing is restarted by using a post-correction program. In this case, if the processing is re-executed from the beginning by using the post-correction program, there is a problem that significant computation resources and waste of time are involved in the re-execution.

On the other hand, for example, if execution target programs as of suspension and as of restarting are the same, the program, data and execution register as of suspension are retained in an auxiliary storage device such that the program is re-started from the retained state. However, when the program is corrected, the content of the program suspended is changed in the program restarted. Therefore, compared with the pre-correction execution binary, the post-correction execution binary has a modified internal structure, and text information being the execution code and the arrangement of data are different. For this reason, state of the pre-correction program as of suspension might not be simply taken over by the post-correction program.

It is desirable to enable a program to be restarted from the suspended position after correction.

Hereinafter, embodiments are described with reference to the accompanying drawings.

### First Embodiment

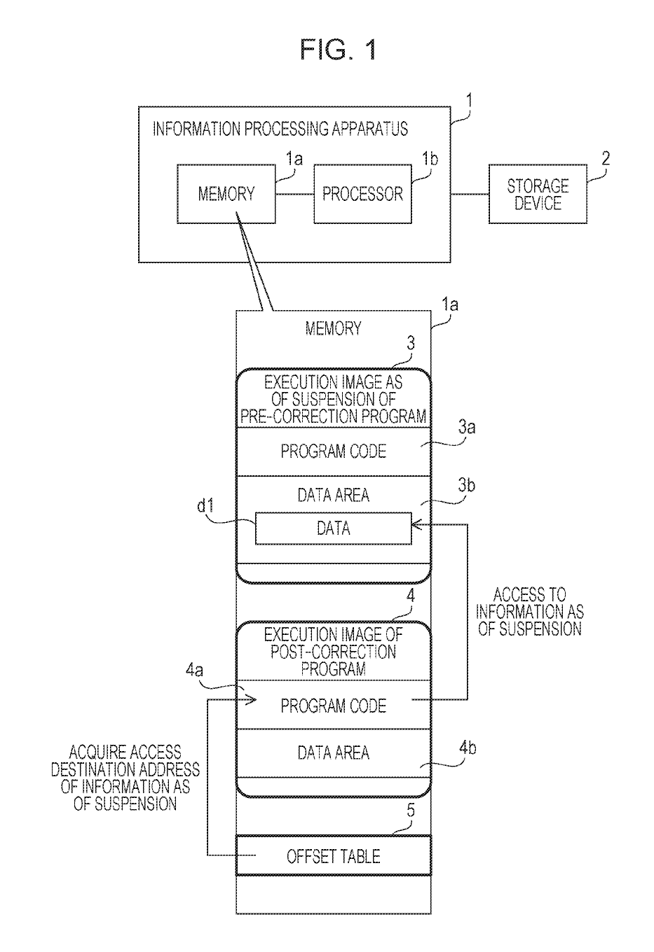

FIG. 1 illustrates an information processing apparatus according to a first embodiment. An information processing apparatus 1 is configured to execute a program. The information processing apparatus 1 includes a memory 1a and a processor 1b. The information processing apparatus 1 may be referred to as a computer.

The memory 1a is a main memory device of the information processing apparatus 1. The memory 1a may be a random access memory (RAM). The processor 1b is a processor of the information processing apparatus 1. The processor 1b may be a central processing unit (CPU). The processor 1b may be an assembly of a plurality of processors (multiprocessor).

The information processing apparatus 1 is coupled to a storage device 2. The storage device 2 is a nonvolatile storage device such as HDD and is an auxiliary storage device (or may be referred to as a secondary storage device) of the information processing apparatus 1. The storage device 2 may be externally mounted into the information processing apparatus 1 or may be incorporated into the information processing apparatus 1. The storage device 2 stores a program executed by the information processing apparatus 1. The program is prepared in advance by the information processing apparatus 1 as data (may be referred to as execution binary) in an executable format. The executable format includes, for example, the executable and linkable format (ELF). However, other executable formats such as EXE, common object file format (COFF) or preferred executable format (PEF) also may be used. The storage device 2 stores various libraries (static shared library and dynamic shared library) used for execution of the program.

The processor 1b stores (loads) a program stored in the storage device 2 into the memory 1a and executes the program. The processor 1b uses a function of a program loader to load the program. The program loader is a program configured to load a newly executed program into the memory 1a. When loading an execution target program, the processor 1b loads a library (dynamic shared library) used in the program into the memory 1a. The processor 1b uses a function of a dynamic linker to load a library. The dynamic linker is a program configured to, when loading a program, load a library used in the program and perform a predetermined setting (dynamic linking processing) such that the library may be used from the program.

Meanwhile, while a program is being executed by the information processing apparatus 1, the program may be corrected. For example, such a case may occur when an error is found in an unexecuted code of the program. In case where a program being executed is corrected, the information processing apparatus 1 suspends execution of a pre-correction program and restarts processing from the beginning by using a post-correction program.

However, re-execution of processing from the beginning wastes execution of the pre-correction program and delays completion of processing. For example, a program that requests three months from execution start to execution completion is considered. In this case, if, at a timing when a first one month has elapsed, a program error is corrected and the information processing apparatus 1 restarts execution of the post-correction program from the beginning, completion of processing takes further three months after the timing. That is, execution completion delays by one month than originally intended. For solving such problems, the information processing apparatus 1 provides a feature of causing a post-correction program to re-use processing results of a pre-correction program and thereby improving program execution efficiency.

The processor 1b suspends execution of the pre-correction program for correction in course of execution of the pre-correction program. The processor 1b stores an execution image 3 as of suspension of the pre-correction program into the storage device 2. The execution image is an image of the execution binary loaded into the memory 1a. The execution image of the program includes a program code as a code body of the program and a data area for storing data referred to by the program code. Functions and data included in the execution image (and execution binary) are identified by an abstract name called a symbol.

For example, the execution image 3 includes a program code 3a and data area 3b. When execution is suspended, the data area 3b includes data d1. The processor 1b stores the execution image 3 into the storage device 2 and thereby holds the state as of suspension of the pre-correction program. In particular, the processor 1b maintains relative arrangement address in the execution image 3 of data d1 included in the execution image 3.

When execution of the pre-correction program is suspended, the processor 1b stores register information (such as program pointer and stack pointer) indicating the execution position (address on the memory 1a) as of suspension of the program, as information indicating the state of the program, in the storage device 2. The processor 1b also stores information of the starting address of the execution image 3 on the memory 1a into the storage device 2. Further, when execution of the pre-correction program is suspended, the processor 1b also stores the content of the stack area and heap area of the program in the memory 1a into the storage device 2.

The storage device 2 stores the post-correction program which is obtained by correcting the pre-correction program, as well as the execution image 3. The information processing apparatus 1 performs the program correction and stores the post-correction program into the storage device 2. For example, the user modifies description of the source program by using the information processing apparatus 1. The processor 1b executes compile processing of the source program and thereby generates object data. The processor 1b executes linking processing of the object data and thereby generates an execution binary corresponding to the post-correction program and stores it into the storage device 2.

When starting execution of the post-correction program, the processor 1b causes the program loader to load the pre-correction program and the post-correction program into the memory 1a. Here, the execution image of the post-correction program is assumed to be an execution image 4. The execution image 4 includes a program code 4a and data area 4b. Here, the arrangement address of the programs on the memory 1a is determined when the programs are loaded (position independent execution format). Therefore, the arrangement address changes every time a program is loaded even if the program is the same. The execution image of the pre-correction program is stored into the memory 1a too, but the state as of suspension is not yet reflected in the data area of the execution image of the pre-correction program.

After loading of the pre-correction program and post-correction program by the program loader, the processor 1b causes the dynamic linker to load a library used for execution of the post-correction program into the memory la. Based on the execution image 3 stored in the storage device 2, the processor 1b writes information as of execution suspension of the pre-correction program into the data area 3b for the pre-correction program loaded into the memory 1a. Then, for example, data d1 retained as of suspension of the pre-correction program is restored in the data area 3b. Thus, the processor 1b restores the execution image 3 being an execution image as of suspension of the pre-correction program onto the memory 1a.

Based on the information as of suspension stored in the data area 3b on the memory 1a, the processor 1b starts execution of the post-correction program from a second position on the post-correction program corresponding to a first position where execution of the pre-correction program is suspended. Here, for example, the processor 1b calculates a relative execution position (relative address) in the execution image 3 as of execution suspension of the pre-correction program by using the starting address of the execution image 3 as of suspension and an address indicated by the program pointer acquired as of suspension. The processor 1b may acquire the address on the memory 1a corresponding to the second position by adding the calculated relative address to the starting address of the execution image 4.

Then, the processor 1b applies contents of the stack pointer, stack area and heap area as of suspension of the pre-correction program to the execution image 4, and starts execution of the post-correction program from the second position by referring to the data area 3b. In this case, the processor 1b does not execute the pre-correction program. Reason for arranging the execution image 3 on the memory 1a is to enable appropriate utilization of data in the data area 3b by the post-correction program.

In particular, the processor 1b refers to respective data in the data area 3b in an appropriate manner during execution of the program code 4a. Reason is as follows: Relative arrangement addresses in the execution image 3 of respective data included in the data area 3b is maintained in the state as of suspension. Thus, the processor 1b may set the relative address (offset) of respective data in the data area 3b relative to the starting address of the execution image 4 to a given area on the memory 1a which may be referred during processing of the program code 4a. For example, the processor 1b generates an offset table 5 indicating the correspondence relationship between the symbol of respective data and the offset in the data area 3b, and arrange the offset table 5 in an area which may be referred from the program code 4a. With this arrangement, the processor 1b applies offset to the starting address of the execution image 4 based on the offset table 5 in the processing of the program code 4a and thereby acquires the absolute address of respective data (for example, data d1) in the data area 3b and accesses the respective data.

Here, the offset table 5 may be a global offset table (GOT) generated for the execution image 4. The GOT is a table mainly used to access the symbol in the dynamic shared library from a program being executed. The GOT is generated by the dynamic linker.

For example, the feature of generating the GOT including information of the offset table 5 may be incorporated into the dynamic linker (dynamic link program). In this case, when performing dynamic linking processing for executing the pre-correction program, the processor 1b records the relative address of respective data in the data area 3b relative to the starting address of the execution image 3 into the GOT of the pre-correction program. Then, the processor 1b also stores the GOT into the storage device 2 when execution of the pre-correction program is suspended. Thus, when performing dynamic linking processing of the post-correction program, the processor 1b generates information corresponding to the offset table 5 from the GOT stored in the storage device 2 and the arrangement address of execution images 3, 4 at that time.

Thus, even when a program being executed is suspended and corrected, the information processing apparatus 1 starts processing with the post-correction program by referring to processing results of the pre-correction program in an appropriate manner. The processor 1b don't have to execute a code portion of the post-correction program corresponding to a code portion already processed by the pre-correction program and thereby reduces time for completing execution of the post-correction program than in a case where the post-correction program is re-executed from the beginning.

Here, for example, data as of suspension may be re-utilized by re-writing the content of the memory 1a with a debugger after loading the post-correction program such that the post-correction program code may be called from the program being executed. However, in this case, rewriting of the instruction at the assembler level is requested. That is, program developers and program users are desired to have a high level technique, and thus only a limited number of users may use the data re-use method involving such operations. Therefore, the method is not suitable to an environment used by many users.

Meanwhile, the information processing apparatus 1 reuses data by using a scheme such as the GOT as described above and thereby provides an advantageous effect that the program developer is not forced to rewrite the content of the memory 1a. Also, this makes easy for the user to use a scheme executing programs efficiently, and thereby utilization efficiency of the information processing apparatus 1 may be improved.

Hereinafter, an embodiment of a server computer (may be referred to as a server) supporting software development is described as an example of the information processing apparatus 1.

### Second Embodiment

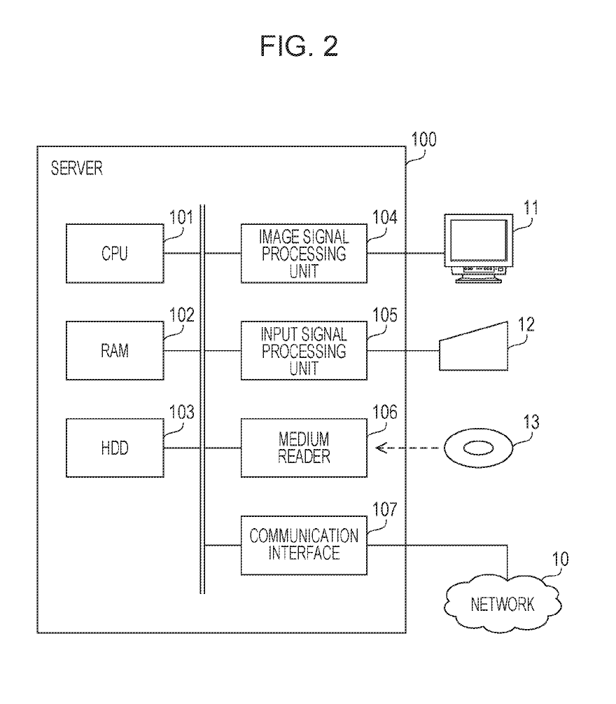

FIG. 2 illustrates a hardware example of a server according to a second embodiment. A server 100 includes a CPU 101, a RAM 102, an HDD 103, an image signal processing unit 104, an input signal processing unit 105, a medium reader 106, and a communication interface 107. These units are coupled to a bus of the server 100.

The CPU 101 is a processor configured to control information processing of the server 100. The CPU 101 may be a multiprocessor.

The RAM 102 is a main memory device of the server 100. The RAM 102 temporarily stores at least a portion of a program of the operating system (OS) executed by the CPU 101 and an application program. The RAM 102 stores various data used for processing by the CPU 101.

The HDD 103 is an auxiliary storage device of the server 100. The HDD 103 magnetically writes and reads data from a built-in magnetic disk. The HDD 103 stores an OS program, an application program, and various data. The server 100 may include an auxiliary storage device of the other type such as a flash memory and solid state drive (SSD), and may include a plurality of auxiliary storage devices.

The image signal processing unit 104 outputs the image to a display 11 coupled to the server 100 according to the instruction from the CPU 101. A cathode ray tube (CRT) display or a liquid crystal display may be used as the display 11.

The input signal processing unit 105 acquires the input signal from an input device 12 coupled to the server 100 and outputs to the CPU 101. For example, a pointing device or a keyboard such as a mouse and a touch panel may be used as the input device 12.

The medium reader 106 is a device configured to read a program or data recorded in a recording medium 13. The recording medium 13 includes, for example, a magnetic disk such as a flexible disk (FD) and a HDD, an optical disc such as a compact disc (CD) or digital versatile disc (DVD), or a magnetic-optical disk (MO). The recording medium 13 also includes, for example, a nonvolatile semiconductor memory such as a flash memory card. The medium reader 106 stores, for example, a program or data read from the recording medium 13 into the RAM 102 or the HDD 103 according to the instruction from the CPU 101.

The communication interface 107 communicates with other devices via a network 10. The communication interface 107 may be a wired communication interface or a radio communication interface.

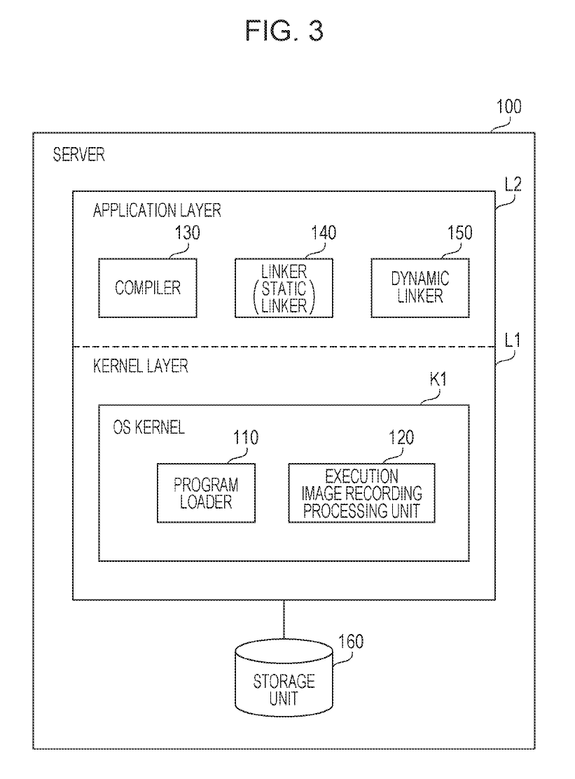

FIG. 3 illustrates a software example of the server. The server 100 has a plurality of hierarchies for the software. A first layer is a kernel layer L1. The kernel layer L1 is a hierarchy to which the OS belongs. A second layer is an application layer L2. The application layer L2 is a hierarchy to which an application program running on the OS belongs. The application layer L2 is a hierarchy higher than the kernel layer L1.

The kernel layer L1 includes an OS kernel K1. The OS kernel K1 is a software serving a core function of the OS. The OS kernel K1 includes a program loader 110 and an execution image recording processing unit 120.

The program loader 110 is configured to load the program. Specifically, the program loader 110 copies an execution binary stored in the HDD 103 into the RAM 102. In this operation, the program loader 110 determines the arrangement address of the storage area on the RAM 102 for the execution binary.

Here, the execution binary is a file in a program executable format and may be referred to as an execution file, an executable file, or an executable format file. File formats of the execution binary include ELF, EXE, COFF, and PEF (for example, a different format is used depending on the type of OS).

The execution binary is generated in the location independent execution format. In the location independent execution format, the execution binary is generated so as to be arranged at any address on the RAM 102, and the address of the loading destination is determined by the program loader 110 when the execution binary is loaded. In the description below, an image of the execution binary loaded into the RAM 102 may be referred to as the execution image.

When executing a post-correction program after suspending execution of a program for correction, the program loader 110 loads a pre-correction program along with the post-correction program. More specifically, the program loader 110 loads an execution image corresponding to the pre-correction program and an execution binary corresponding to the post-correction program into the RAM 102. In this operation, the program loader 110 arranges the execution image corresponding to the pre-correction program and the execution binary corresponding to the post-correction program such that storage areas of the execution binaries occupied in the RAM 102 do not overlap each other. The program loader 110 causes a dynamic linker 150 to start execution of the post-correction program from a predetermined address position on the post-correction program corresponding to a position where execution of the pre-correction program is suspended.

When suspending execution of a program for correction, the execution image recording processing unit 120 acquires information on the execution image of the program and stores the information into the HDD 103 to re-use processing results of the pre-correction program in processing of the post-correction program.

The application layer L2 includes a compiler 130, a linker 140, and the dynamic linker 150.

The compiler 130 is configured to compile the source file. The source file is a file including source codes described by the user. Upon entry of a source file, the compiler 130 generates an object file from the source file and stores the object file into the HDD 103. Here, the compiler 130 generates a program code in the object file such that data (may be referred to as the data element or the data block) included in the execution binary may be indirectly referred to via the GOT.

The linker 140 performs a processing of linking one or more object files generated by the compiler 130 and one or more libraries (in this case, static shared library) with each other (hereinafter referred to as the static linking processing). The linker 140 generates a program in an executable format (execution binary) as a result of the static link processing and stores the same into the HDD 103. For example, the linker 140 rearranges a plurality of subprograms with the address 0 as a reference respectively (by binding a symbol in each of the subprograms into a relative address) and generates one execution binary starting from the address 0. Here, in addition to a normal static link processing, the linker 140 sets a symbol table in the execution binary such that data included in the execution binary may be referred to via the GOT. The linker 140 may be referred to as the static linker.

When loading a program, the dynamic linker 150 performs dynamic linking processing that links the program and the dynamic shared library with each other. The dynamic linker 150 solves the symbol in the dynamic shared library and registers information of the reference destination address corresponding to the symbol into the GOT of the program. Further, in addition to the normal dynamic linking processing, the dynamic linker 150 records information of the reference destination address of data included in the execution binary into the GOT. The dynamic linker 150 generates the GOT for each of programs (for each of execution binaries).

When executing the post-correction program, the dynamic linker 150 reads symbol information in an execution image corresponding to the pre-correction program and writes information of the arrangement destination address of respective data in the execution image into a GOT corresponding to a post-correction execution binary. Thus, in processing of the post-correction program, the dynamic linker 150 enables reference to data areas in the execution image corresponding to the pre-correction program in place of data areas in the execution binary corresponding to the post-correction program.

A storage unit 160 is a storage area secured in the HDD 103. The storage unit 160 stores the source file, object file, execution binary, static shared library, dynamic shared library, and various information acquired by the execution image recording processing unit 120.

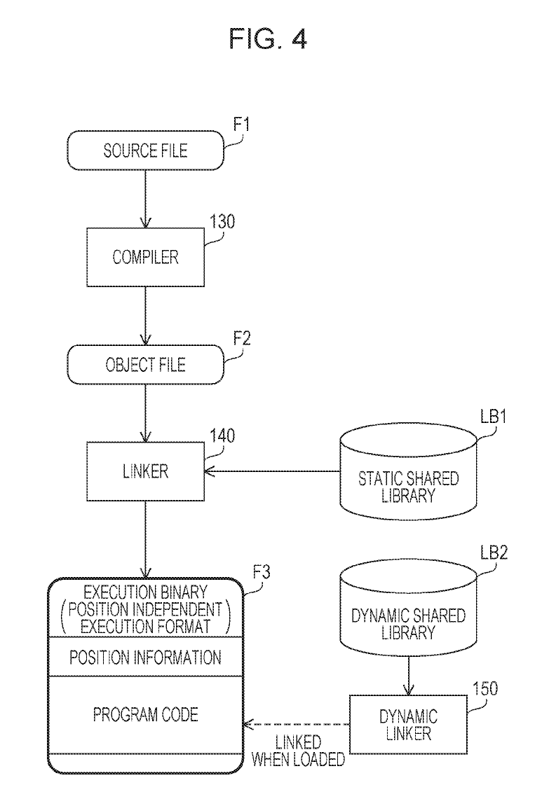

FIG. 4 illustrates an example of execution binary generation. A source file F1 is prepared and stored into the storage unit 160 by the user. For example, the user may describe the code into the source file F1 by operating the input device 12.

Upon entry of the source file F1, the compiler 130 generates an object file F2 according to the code described in the source file F1. In this operation, the compiler 130 generates a program code in the object file F2 such that respective symbols may be indirectly referred by the GOT.

The linker 140 performs static link processing based on the object file F2 and a static shared library LB1 and generates an execution binary F3. As described above, the execution binary F3 is a file in the location independent execution format. The execution binary F3 includes position information and program code. The position information is information indicating the address of the symbol referred to by the program code. Here, the position information registers a relative address for the symbol with the starting address “0” of the execution binary F3 as a reference.

The execution binary F3 also includes a symbol table (not illustrated in FIG. 4) where the symbol attribution is registered. The linker 140 sets the symbol table such that respective symbols included in the execution binary F3 are referred to via the GOT.

When loading the execution binary F3 into the RAM 102, the dynamic linker 150 performs dynamic linking processing between the execution binary F3 and a dynamic shared library LB2. Also, based on position information included in the execution binary F3, the dynamic linker 150 records the symbol and address information of the symbol (relative address with the starting address of the execution binary F3 as a reference) into the GOT for the execution binary F3

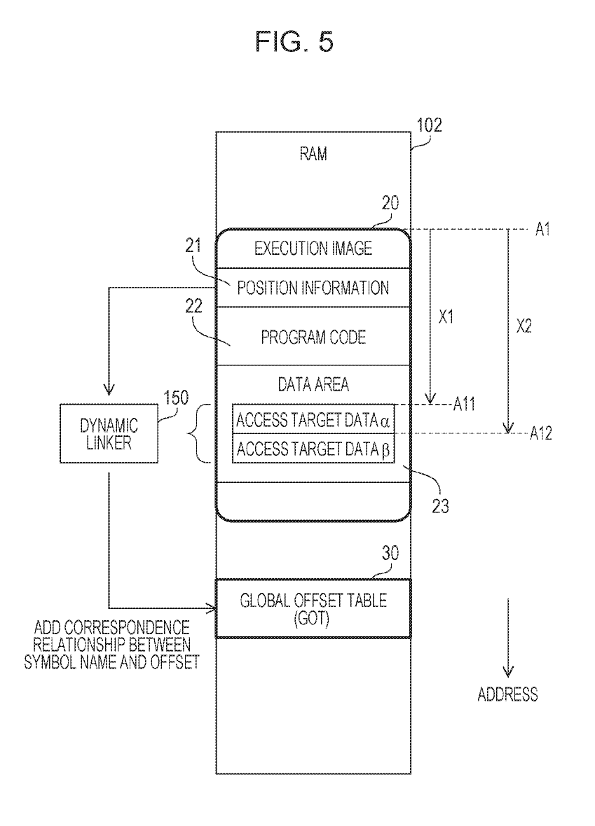

FIG. 5 illustrates an example of information added to GOT. Assume that the execution image of the execution binary F3 loaded onto the RAM 102 is an execution image 20. The execution image 20 includes position information 21, a program code 22, and a data area 23. Here, the address (starting address) on the RAM 102, where the execution image 20 is arranged, is an address A1. The address A1 is an absolute address on the RAM 102. The position information 21 includes information of the address of the symbol referred to for executing processing of the program code 22. Information of the address of the symbol is represented by a relative address of an area where the content of the symbol in the data area 23 is stored, with the address A1 as a reference. In FIG. 5, direction from top to bottom represents positive direction of the address on the RAM 102.

For example, the data area 23 includes an area for storing data of symbol names “α”, “β”. Hereinafter, data of the symbol name “α” may be referred to as the access target data α. The position information 21 includes information on the correspondence relationship between the symbol name “α” and a relative address X1 and the correspondence relationship between the symbol name “β” and a relative address X2. In this case, the absolute address of the access target data α on the RAM 102 is an address A11 (A11=A1+X1).

The absolute address of the access target data β on the RAM 102 is an address A12(A12=A1+X2).

The dynamic linker 150 adds the correspondence relationship between the symbol name “α” and the relative address X1 to a GOT 30 corresponding to the execution image 20. The dynamic linker 150 adds the correspondence relationship between the symbol name “β” and the relative address X2 to the GOT 30. Here, the GOT 30 is arranged at a predetermined relative address with respect to the address of the execution image 20. Thus, the dynamic linker 150 and the program code 22 may access the GOT 30 of the execution image 20 through the relative address.

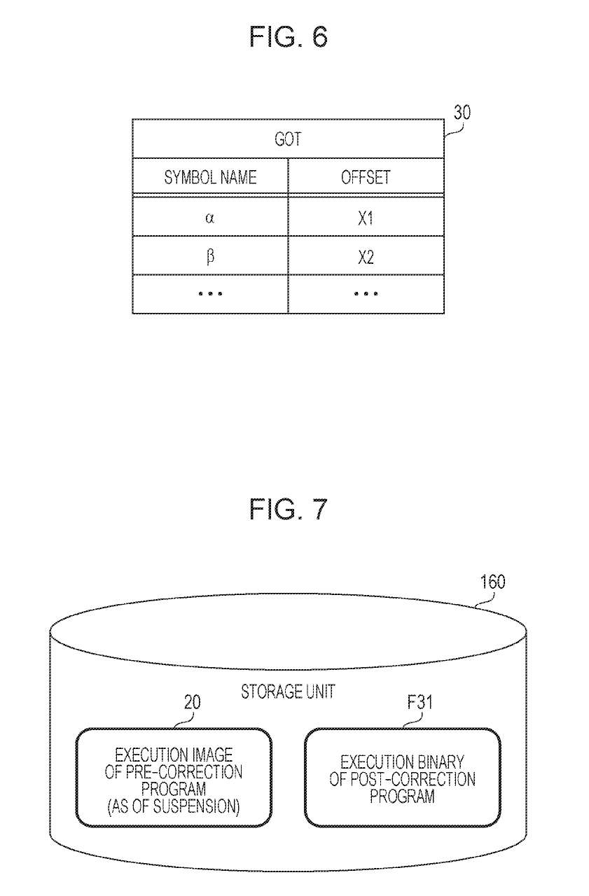

FIG. 6 illustrates an example of the GOT. The GOT 30 includes symbol name and offset fields. The symbol name field registers the symbol name. The offset field registers the relative address (offset) with the starting address of the execution image 20 as a reference.

For example, the GOT 30 includes information of the symbol name “α” and the offset “X1”. This indicates that the access target data α included in the data area 23 is arranged at the position of the relative address “X1” with the starting address of the execution image 20 as a reference.

The GOT 30 also includes information of the symbol name “β” and the offset “X2”. This indicates that the access target data p included in the data area 23 is arranged at the position of the relative address “X2” with the starting address of the execution image 20 as a reference.

Thus, in addition to the address information of the normal dynamic shared library, the dynamic linker 150 also registers the address information of symbols included in the data area 23 of the execution image 20 into the GOT 30.

FIG. 7 illustrates an example of information stored in the storage unit. A storage unit 160 stores the execution image 20 of the pre-correction program and an execution binary F31 of the post-correction program. The execution image 20 is acquired by the execution image recording processing unit 120 when execution of the pre-correction program is suspended. The execution binary F31 is an executable file generated by the compiler 130 and the linker 140 based on a post-correction source file generated through correction of the source file F1 by the user. For example, out of codes in the source file F1, the user may correct description of a code corresponding to an unexecuted portion of the program code 22 in the execution image 20. The execution binary F31 reflects correction of the code.

As described above, the storage unit 160 stores a plurality of source files including the source file F1, a plurality of object files including the object file F2, and a plurality of execution binaries including the execution binary F3, in addition to information illustrated in FIG. 7. The storage unit 160 pre-stores the static shared library LB1 and the dynamic shared library LB2. The storage unit 160 stores information representing the state of the execution image 20 as of suspension. Specifically, the storage unit 160 also stores register information of the CPU 101 acquired by the execution image recording processing unit 120, the content of the stack memory for the execution image 20, the content of the dynamic data area (such as a heap area), and the content of the GOT 30.

Next, a processing procedure for the server 100 starting an application with the post-correction program is described.

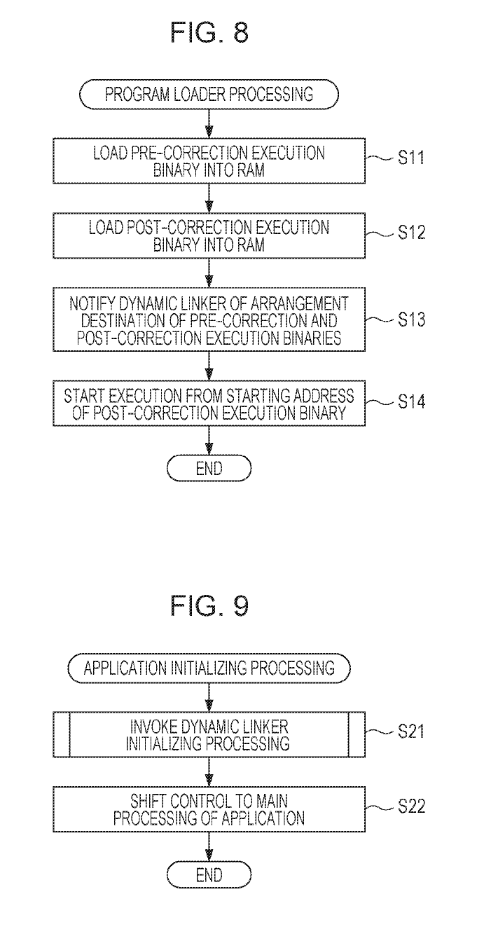

FIG. 8 illustrates an example of program loader processing. Hereinafter, the processing illustrated in FIG. 8 is described in the order of step numbers.

(S11) The program loader 110 receives a start-up instruction from an application. For example, the user may enter the start-up instruction of the application into the server 100 by using an input device 12. The program loader 110 acquires a pre-correction execution binary F3 from a storage unit 160 and loads into a RAM 102. The program loader 110 may perform the loading based on the execution image 20 stored in the storage unit 160. In this operation, the program loader 110 determines the beginning address where the execution binary F3 is arranged.

(S12) The program loader 110 acquires the post-correction execution binary F31 from the storage unit 160 and loads into the RAM 102. In this operation, the program loader 110 determines the beginning address where the execution binary F31 is arranged. The program loader 110 also loads the execution binary F31 into an area not overlapping an area of the execution binary F3 on the RAM 102.

(S13) The program loader 110 notifies the dynamic linker 150 of the arrangement destination of pre-correction and post-correction execution binaries (or execution binaries F3, F31). Then, the dynamic linker 150 is activated, for example, by the OS after the execution binary F31 is loaded.

(S14) The program loader 110 receives notification of the starting address of the post-correction execution binary F31 from the dynamic linker 150. Then, the program loader 110 starts execution from the starting address of the post-correction execution binary F31.

FIG. 9 illustrates an example of application initializing processing. Hereinafter, the processing illustrated in FIG. 9 is described in the order of step numbers.

(S21) The OS invokes initializing processing of the dynamic linker 150. The step S21 may be performed immediately after the step S13.

(S22) The OS shifts control to main processing of the application. However, as described in the step S14, in the case where the starting address of the execution binary F31 is notified to the program loader 110 by the dynamic linker 150, the step S22 is skipped.

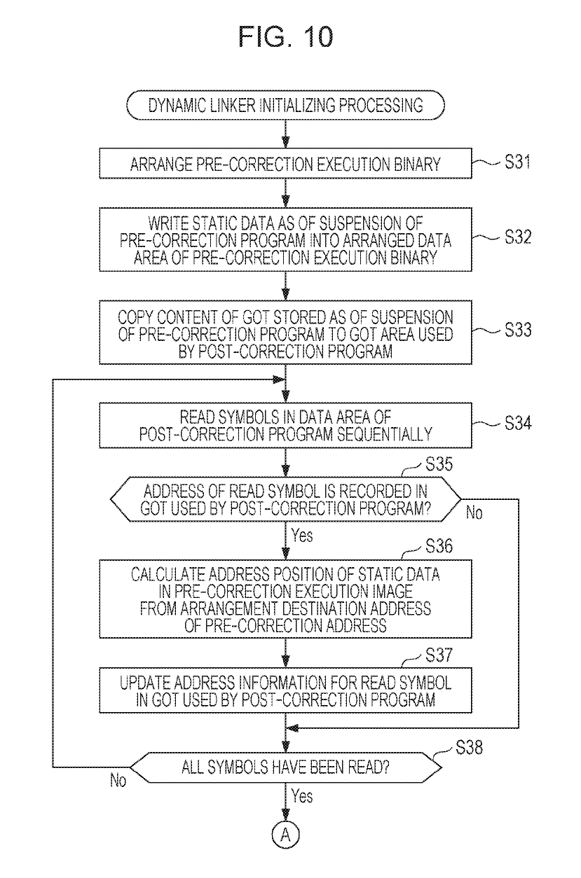

FIG. 10 illustrates an example of dynamic linker initializing processing. Hereinafter, the processing illustrated in FIG. 10 is described in the order of step numbers. The processing described below corresponds to the step S21 of FIG. 9.

(S31) The dynamic linker 150 arranges the pre-correction execution binary F3 onto the RAM 102. Thus, the dynamic linker 150 recognizes, for example, the arrangement of the program code 22 and data area 23 in the execution image 20.

(S32) The dynamic linker 150 writes static data (content of the data area 23) as of suspension of the pre-correction program stored in the storage unit 160 into the data area 23 of the pre-correction execution binary F3 arranged this time. Specifically, the dynamic linker 150 restores the content of the data area 23 by maintaining the relative address in the execution image 20 as of suspension. Thus, the dynamic linker 150 writes information as of execution suspension of the pre-correction program into the data area 23 arranged this time and thereby restores the execution image 20 as of execution suspension of the pre-correction program on the RAM 102.

(S33) The dynamic linker 150 acquires the content of the GOT 30 stored as of suspension of the pre-correction program from the storage unit 160, and copies the content of the GOT 30 into a GOT area used by the post-correction program (execution binary F31).

(S34) The dynamic linker 150 reads symbols in the data area of the post-correction program sequentially. In this operation, the dynamic linker 150 detects a plurality of symbols used by the post-correction program by analyzing the program code (content of the text area) of the post-correction execution binary. The dynamic linker 150 reads symbols one by one out of the plurality of symbols thus detected and executes the following procedure.

(S35) The dynamic linker 150 determines whether the address of the read symbol is recorded in the GOT used by the post-correction program. When the address is recorded, the dynamic linker 150 proceeds the processing to the step S36. When the address is not recorded, the dynamic linker 150 proceeds the processing to the step S38. In this operation, the dynamic linker 150 performs determination of the step S35 by verifying whether the read symbol is registered in the GOT of the post-correction program.

(S36) The dynamic linker 150 calculates the address position of static data (the corresponding symbol in the data area 23) within the pre-correction execution image 20, from the arrangement destination address of the pre-correction program. A specific calculation method is described later. As the address position, the dynamic linker 150 calculates the relative address with the beginning address of the execution binary F31 as a reference.

(S37) The dynamic linker 150 updates address information for the read symbol in the GOT used by the post-correction program with the address position calculated in the step S36.

(S38) The dynamic linker 150 determines whether all symbols have been read. When all symbols have been read, the dynamic linker 150 proceeds the processing to the step S39. When there exists a symbol that has not been read, the dynamic linker 150 proceeds the processing to the step S34.

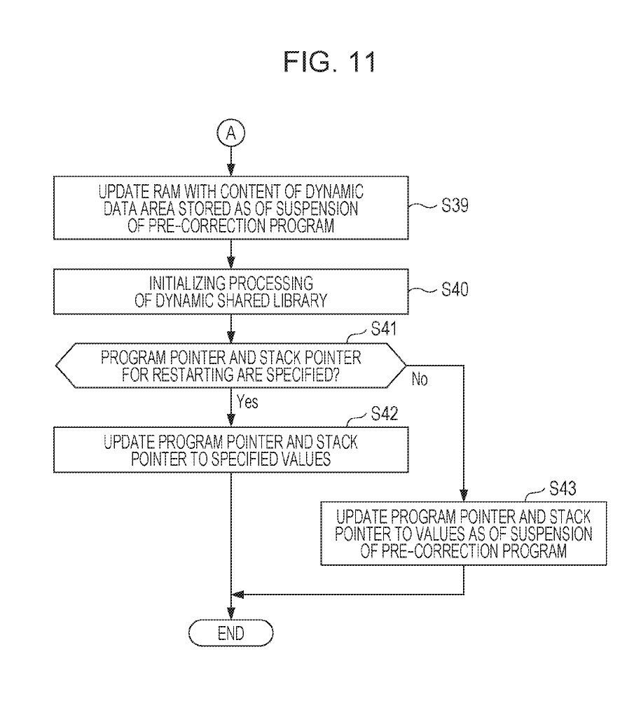

FIG. 11 illustrates an example of dynamic linker initializing processing (continued). Hereinafter, the processing illustrated in FIG. 11 is described in the order of step numbers.

(S39) The dynamic linker 150 acquires the content of the dynamic data area stored as of suspension of the pre-correction program from the storage unit 160, and updates the RAM 102 with the content of the dynamic data area.

(S40) The dynamic linker 150 performs initializing processing of the dynamic shared library. Based on the content of the dynamic data area restored in the step S39, the dynamic linker 150 restores the state of the dynamic shared library as of suspension of the pre-correction program.

(S41) The dynamic linker 150 determines whether the program pointer and stack pointer for restarting are specified. When the pointers are specified, the dynamic linker 150 proceeds the processing to the step S42. When the pointers are not specified, the dynamic linker 150 proceeds the processing to the step S43. For example, the user may enter the program pointer indicating the execution starting position on the post-correction program and the stack pointer indicating the execution trajectory (for example, the trajectory of branching) up to the execution starting position, into the server 100 along with the execution instruction of the post-correction program.

(S42) The dynamic linker 150 updates the program pointer and stack pointer to specified values and notifies the program loader 110 of the updated results (notification of the starting address). Then, the processing ends.

(S43) The dynamic linker 150 updates the program pointer and stack pointer to values as of suspension of the pre-correction program and notifies the program loader 110 of the results (notification of the starting address). In this operation, the dynamic linker 150 acquires the program pointer and stack pointer as of suspension of the pre-correction program from the storage unit 160. Then, the processing ends.

Next, a procedure of the processing of the execution image recording processing unit 120 as of suspension of the pre-correction program is described.

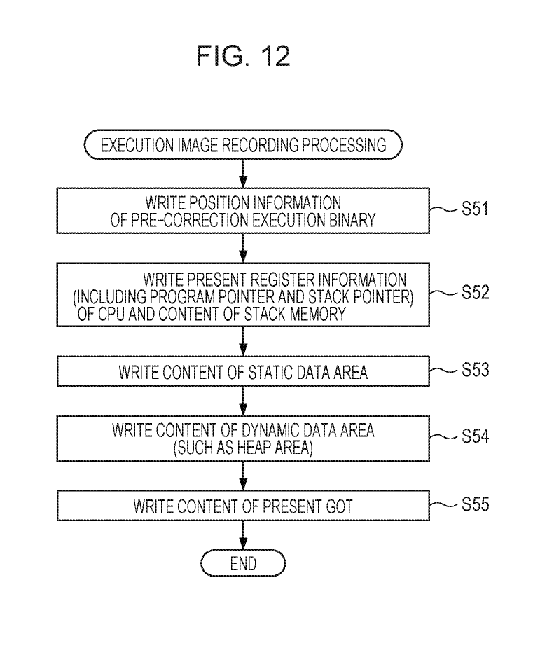

FIG. 12 illustrates an example of the execution image recording processing. Hereinafter, the processing illustrated in FIG. 12 is described in the order of step numbers.

(S51) Upon detecting forced termination of the pre-correction program, the execution image recording processing unit 120 writes position information (position information 21 of the execution image 20) of the pre-correction execution binary F3 into the storage unit 160. The position information 21 includes information of the program code 22, data area 23, and relative address of respective symbols, with the starting address of the execution binary F3 as a reference.

(S52) The execution image recording processing unit 120 writes current register information (including the program pointer and stack pointer) of the CPU 101 and the content of the stack memory (content of the stack memory for the execution binary F3) into the storage unit 160.

(S53) The execution image recording processing unit 120 writes the content of the static data area (data area 23) for the execution image 20 into the storage unit 160.

(S54) The execution image recording processing unit 120 writes the content of the dynamic data area (such as heap area) for the execution image 20 into the storage unit 160.

(S55) The execution image recording processing unit 120 writes the current content of the GOT 30 for the execution image 20 into the storage unit 160.

Thus, the execution image recording processing unit 120 acquires the state of the pre-correction program as of suspension (as of forced termination) and stores the state into the storage unit 160 in association with the pre-correction program (for example, execution binary F3).

In this operation, the execution image recording processing unit 120 acquires, for example, the execution position on the program code 22 as of suspension of the pre-correction program as a relative address from the beginning address of the execution image 20 as of the suspension. Then, when the starting position on the post-correction program is not specified by the user, the dynamic linker 150 starts execution of the post-correction program from an address indicated by the relative address from the beginning address where the post-correction program is arranged. Meanwhile, when the starting position is specified, the dynamic linker 150 starts execution of the post-correction program from the starting position.

Next, a method for updating the address of respective symbols (static data) indicated in steps S36 and S37 of FIG. 10 is described.

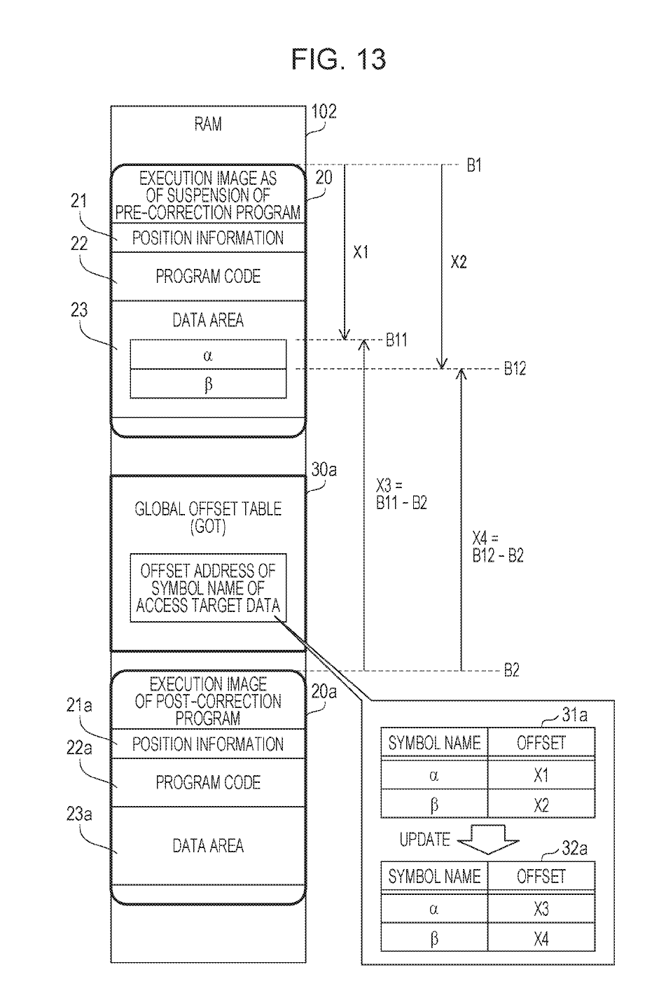

FIG. 13 illustrates an example of offset updating of the GOT. Here, to execute the post-correction program, an execution image 20 as of suspension of the pre-correction program and an execution image 20a of the post-correction program are arranged on the RAM 102. The execution image 20a includes position information 21a, a program code 22a, and a data area 23a. A GOT 30a used by the post-correction program is arranged on the RAM 102. The GOT 30a includes address information 31a on the execution image 20 stored in the storage unit 160. The address information 31a includes an offset X1 of access target data α and an offset X2 of access target data β.

The dynamic linker 150 updates the address information 31a included in the GOT 30a to address information 32a as follows.

The dynamic linker 150 receives notification of a beginning address B1 of the execution image 20 and a beginning address B2 of the execution image 20a from the program loader 110. Addresses B1 and B2 are absolute addresses. In this case, according to the address information 31a included in the GOT 30a, an arrangement address B11 of the access target data α is B11=B1+X1. An arrangement address B12 of the access target data 13 is B12=B1+X2.

Therefore, with the starting address B2 of the execution image 20a as a reference, the relative address (offset) of the access target data α is X3=B11−B2=B1+X1−B2. In the same manner, with the starting address B2 as a reference, the relative address (offset) of the access target data r3 is X4=B12−B2=B1+X2−B2. Thus, in the GOT 30a, the dynamic linker 150 updates the offset of the access target data α to “X3” and the offset of the access target data 13 to “X4”. The address information 32a reflects the updated offsets.

Thus, based on a first offset (for example, X1) of the data area 23 with the first address (for example, B1) of the pre-correction program as a reference, the dynamic linker 150 calculates a second offset (for example, X3) of the data area 23 with the second address (for example, B2) of the post-correction program as a reference, and adds the second offset to the GOT 30a. In this operation, the dynamic linker 150 calculates the second offset of each of plural pieces of data based on the first offset of each of plural pieces of data included in the data area 23. The post-correction program (application) able to access respective symbols in the data area 23 of the execution image 20 in an appropriate manner by solving the symbols with the GOT 30a.

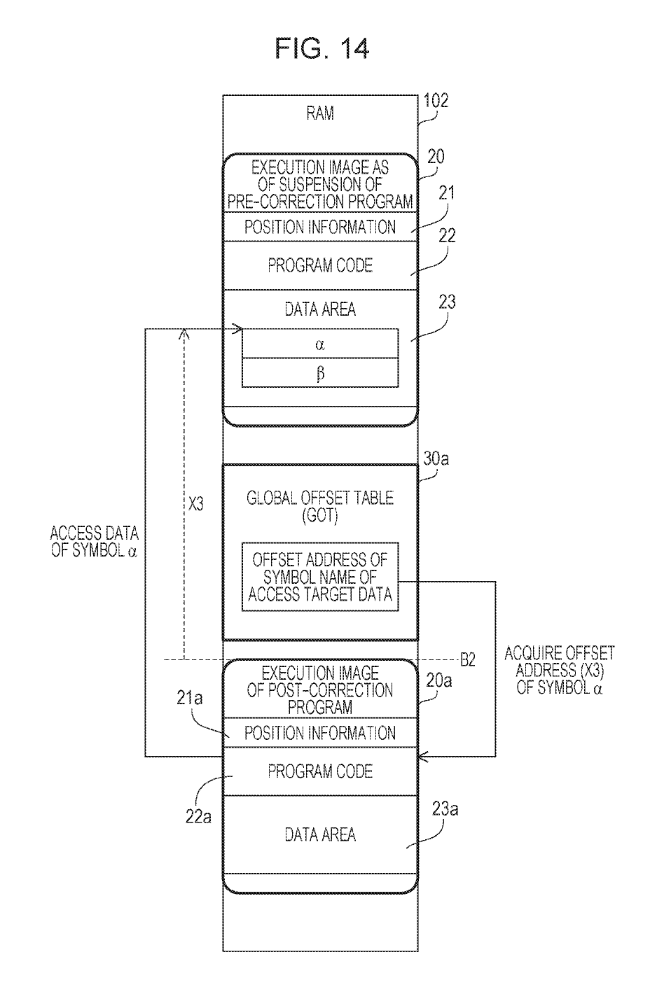

FIG. 14 illustrates an example of data access by the post-correction program. For example, when accessing a symbol a (access target data a), the application acquires an offset address “X3” of the symbol a from the GOT 30a. The application obtains an address B11 (absolute address) of the access target data α by calculating the address B11=B2+X3. Then, the application accesses the address B11 on the RAM 102 and thereby accesses the access target data α existing in the data area 23.

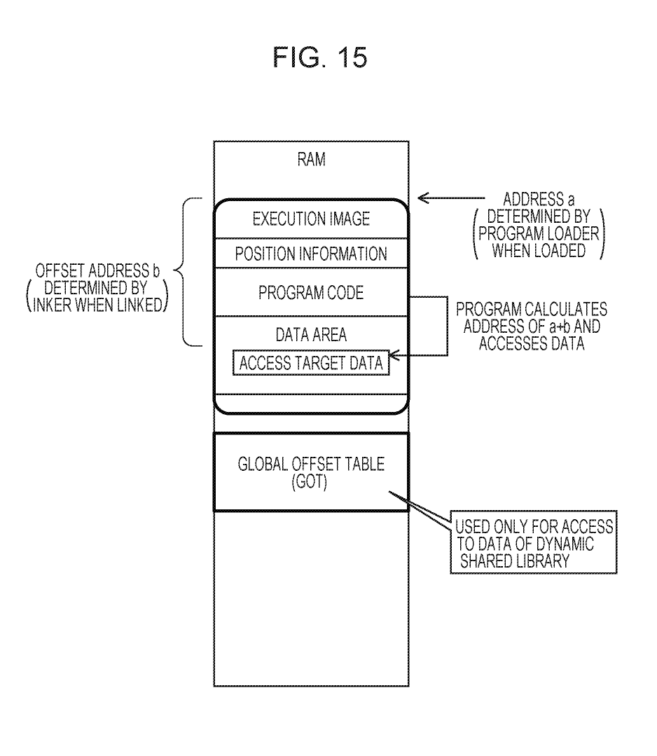

FIG. 15 illustrates a comparison example of program execution images. When loading the execution binary, the program loader determines a beginning address a of the execution image corresponding to the execution binary. An offset address b from the beginning address a of the access target data in the data area of the execution image is determined by the linker (static linker) when performing linking. Information of the beginning address a and offset address b is included in the position information in the execution image but not recorded in the GOT. In this case, to access the access target data in the processing of the program code, the application determines an address a+b (absolute address) by adding the offset address b to the beginning address a by referring to the position information. The application accesses the access target data by setting the access destination address at a+b. In the example of FIG. 15, the GOT is used only for access to data in the dynamic shared library and not used for solving the symbol in the data area.

If execution images before suspension and after restarting are the same, the execution images may be retained, and the arrangement address of the access target data in the data area may be acquired from the position information of the execution images that is retained after restarting. An example of a method for performing execution suspension and execution restarting of the same program includes a method called check point restart.

However, when a program is corrected, the content of the program suspended is changed in the program restarted. Therefore, compared with the pre-correction execution binary, the post-correction execution binary has a modified internal structure, and the arrangement addresses of text information and data included in the execution code are different within the execution binary. Thus, the state as of suspension of the pre-correction program might not be simply taken over by the post-correction program like the check point restarting method. Consequently, a scheme, that enables the program code of the post-correction execution image to reference the static data retained by an execution image as of suspension, is requested.

For example, data as of suspension may be re-used by re-writing the content of the RAM 102 after loading such that the post-correction program code is called from a program being executed (pre-correction program) by using a debugger, etc. However, in this case, rewriting of the instruction at the assembler level is requested. That is, program developers and program users are desired to have a high level technique, and therefore, the data re-use method involving such operations is not realistic.

Meanwhile, the server 100 causes the dynamic linker 150 to reuse data by using a scheme of the GOT and thereby provides an advantageous effect that the program developer is not forced to rewrite the content of the RAM 102. This makes easy for the user to use a scheme executing the program efficiently, and thereby utilization efficiency of the server 100 may be improved.

Then, even when a program being executed is suspended and corrected, the server 100 may start processing with the post-correction program by referring to processing results of the pre-correction program in an appropriate manner. The server 100 requests not to execute a code portion of the post-correction program corresponding to a code portion already processed by the pre-correction program and thereby may reduce time for completing execution of the post-correction program than in a case where the post-correction program is re-executed from the beginning.

The program restarting method according to the second embodiment also may be applied to a high performance computing (HPC) system. In many cases of the HPC system, computing resources are leased to a plurality of users, and users perform relatively large-scale computing during the lease period. The period when the user is allowed to use the computing resource is limited. Therefore, the computing resource is preferably operated in such a manner not causing useless computation. Also, operation not causing useless computation is preferable from the viewpoint of the power consumed for the operation. By applying functions of the dynamic linker 150 to the HPC system too, pre-correction execution results may be reused even when correction to the program occurs during execution thereof, and thereby occurrence of useless computation may be avoided. As a result, time taken for execution of the program may be reduced. Also, power saving of the system may be achieved. The program restarting method according to the second embodiment is useful particularly for a program involving computation for a relatively long period (for example, such as few days, few weeks, and few months).

Next, another example of the dynamic linker initializing processing is described. For example, the dynamic linker 150 may unmap the data area 23a of the post-correction execution image 20a to achieve memory saving.

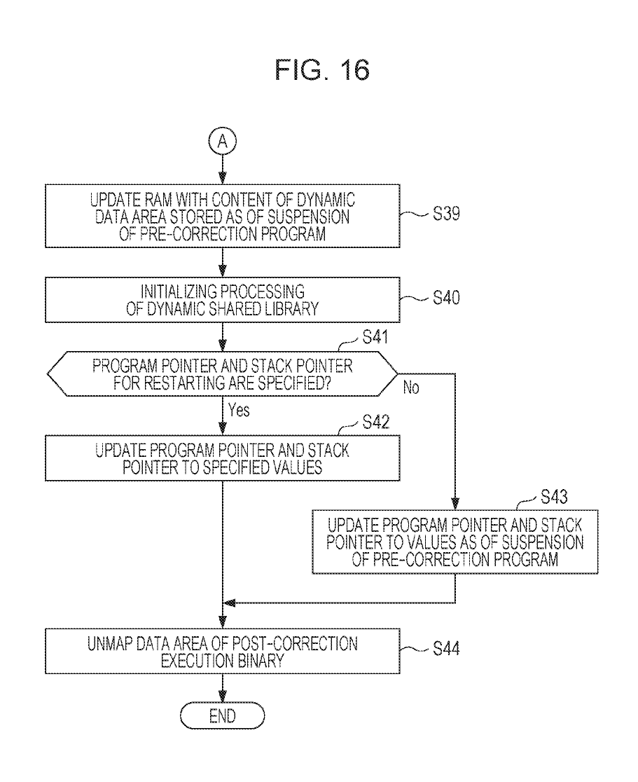

FIG. 16 is an example of an operational flowchart for the dynamic linker initializing processing. Hereinafter, the processing illustrated in FIG. 16 is described in the order of step numbers. After the steps of FIG. 10, the dynamic linker 150 may execute a step S44 described below in addition to the steps (steps S39 to S43) of FIG. 11. The step S44 is executed next to the step S42 or step S43.

(S44) The dynamic linker 150 unmaps the data area 23a corresponding to the post-correction execution binary F31. That is, the dynamic linker 150 cancels arrangement of the data area 23a on the RAM 102.

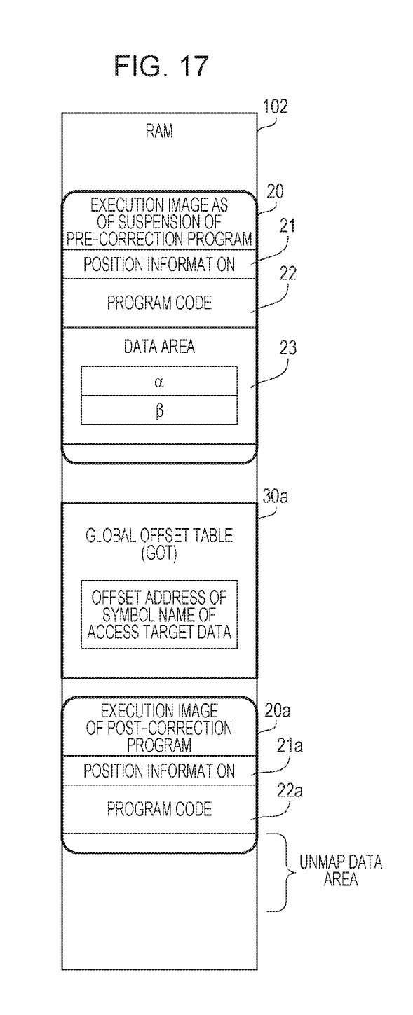

FIG. 17 illustrates an example of the unmapped data area. As illustrated in FIG. 14, an application implemented by the execution image 20a executes processing by referring to the data area 23. Thus, the data area 23a is an area not used. Thus, the dynamic linker 150 may turn a storage area corresponding to the data area 23a on the RAM 102 into a free state by unmapping the data area 23a in the execution image 20a. This achieves memory saving.

Meanwhile, the dynamic linker 150 also may control such that both data areas 23, 23a are used by the application. In this case, the execution image recording processing unit 120 performs execution image recording processing as described below at the time the pre-correction program is suspended, in place of the procedure of FIG. 12.

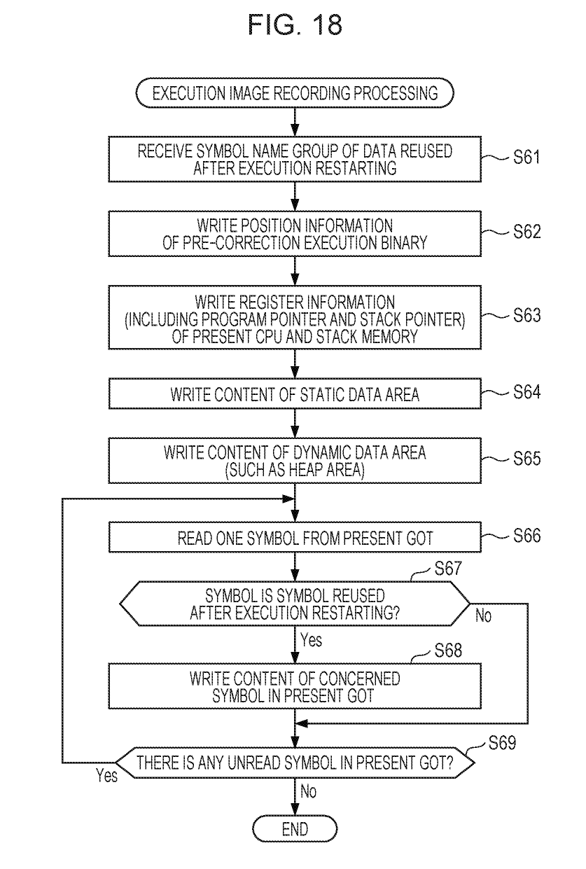

FIG. 18 is an example of an operational flowchart for the execution image recording processing. Hereinafter, the processing illustrated in FIG. 18 is described in the order of step numbers.

(S61) The execution image recording processing unit 120 detects forced termination of the pre-correction program. The execution image recording processing unit 120 receives a symbol name group of data re-used after restarting of execution, out of processed data.

(S62) The execution image recording processing unit 120 writes position information (position information 21 of the execution image 20) of the pre-correction execution binary F3 into the storage unit 160. The position information 21 includes information of the program code 22, data area 23, and relative address of respective symbols, with the starting address of the execution binary F3 as a reference.

(S63) The execution image recording processing unit 120 writes register information (including the program pointer and stack pointer) of the present CPU 101 and the content of the stack memory (content of the stack memory for the execution binary F3) into the storage unit 160.

(S64) The execution image recording processing unit 120 writes the content of the static data area (data area 23) for the execution image 20 into the storage unit 160.

(S65) The execution image recording processing unit 120 writes the content of the dynamic data area (such as heap area) for the execution image 20 into the storage unit 160.

(S66) The execution image recording processing unit 120 reads one symbol from the present GOT 30 for the execution image 20.

(S67) The execution image recording processing unit 120 determines whether the read symbol is a symbol to be re-used after restarting of execution. When the symbol is a symbol to be re-used after restarting execution, processing proceeds to the step S68. When the symbol is not a symbol to be re-used after restarting execution, processing proceeds to the step S69. In this operation, when the read symbol is included in the symbol name group received in the step S61, the execution image recording processing unit 120 determines that the symbol is a symbol to be re-used after restarting of execution. When the read symbol is not included in the symbol name group received in the step S61, the execution image recording processing unit 120 determines that the symbol is not a symbol to be re-used after restarting of execution.

(S68) The execution image recording processing unit 120 writes the content of the present GOT 30 for the concerned symbol into the storage unit 160.

(S69) The execution image recording processing unit 120 determines whether there is any unread symbol in the present GOT 30. When there is any unread symbol, processing proceeds to the step S66. When there is not an unread symbol, processing ends.

Thus, out of symbols stored in the GOT 30, the execution image recording processing unit 120 stores only the offsets of symbols specified for reuse after execution restarting by the post-correction program, into the storage unit 160. As mentioned above, the user may cause the execution image recording processing unit to change the data reference destination of the post-correction program depending on a symbol, by entering the symbol name group of data re-used after execution restarting into the server 100.

To change the reference destination, the compiler 130 and linker 140 generate the program code and set the symbol table so as to access the symbol name group received in the step S61 by indirect reference via the GOT. For symbols not included in the symbol name group received in the step S61 (symbols in the execution binary), the compiler 130 and linker 140 generate the program code and set the symbol table so as to access in a normal manner. Thus, the compiler 130 and linker 140 generate an execution binary which is set to refer to the data area of the pre-correction program for some symbols and to refer to the data area of the post-correction program for other symbols.

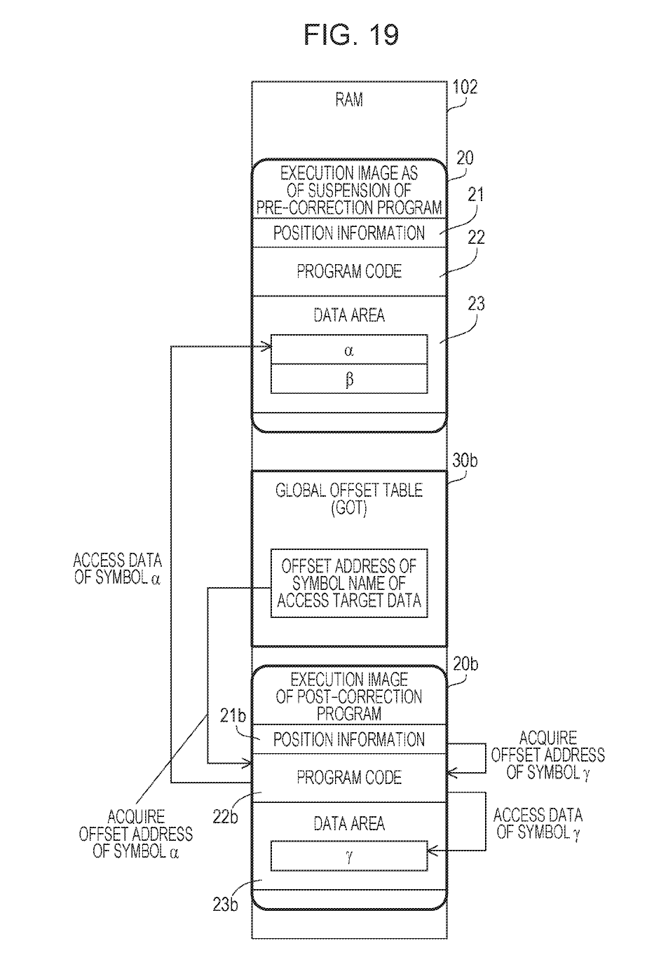

FIG. 19 illustrates another example of data access by the post-correction program. Here, the execution image 20 as of suspension of the pre-correction program and an execution image 20b of the post-correction program are arranged on the RAM 102 to execute the post-correction program. The execution image 20b includes position information 21b, a program code 22b, and a data area 23b. A GOT 30b is arranged on the RAM 102 for the execution image 20b.

The dynamic linker 150 executes steps of FIG. 10 and FIG. 11 based on the GOT acquired by the execution image recording processing unit 120 in the steps of FIG. 18, and changes the reference destination of respective symbols included in data areas 23, 23b. For example, both of execution images 20, 20b include symbols of symbol names “α”, “β”, “γ”. However, in FIG. 19, illustration of the symbol name “γ” is omitted in the data area 23. In FIG. 19, illustration of the symbol names “α” and “β” are omitted in the data area 23b.

Here, assume that “α” and “β” are specified in the step S61 of FIG. 18 as symbol name groups re-used after execution restarting. In this case, the dynamic linker 150 registers access information on access target data α, β into the GOT 30b, but does not register access information on access target data γ into the GOT 30b. Thus, the application implemented by the execution image 20b accesses access target data a, p included in the data area 23 based on the GOT 30b. Meanwhile, the application accesses access target data y included in the data area 23b based on the position information 21b.

Thus, when processing the program code 22b, the dynamic linker 150 also may control so as to change the reference destination to either of data areas 23, 23b for each symbol. The dynamic linker 150 determines whether access destination on the RAM 102 for each of plural pieces of data referred to by the post-correction program is the data area 23 of the pre-correction program or the data area 23b of the post-correction program. Thus, control of the reference destination for each symbol by the application may be made flexible.

Information processing according to the first embodiment may be implemented by causing the processor 1b to execute the program. Information processing according to the second embodiment may be implemented by causing the CPU 101 to execute the program. The program may be recorded in a computer readable recording medium 13.

For example, the program may be distributed by distributing the recording medium 13 that records the program. Also, the program may be stored in another computer and distributed via network. For example, the computer may store (or install) a program recorded in the recording medium 13 or received from another computer into a storage device such as the RAM 102 or HDD 103 and execute the program by reading from the storage device.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An apparatus comprising:
a memory; and
a processor coupled to the memory and configured to:
cause a program loader to load a first program and a second program that is obtained by correcting the first program, into the memory;
cause a linker to load a library used for execution of the second program into the memory;
write first data that has been processed at a suspension time at which execution of the first program is suspended, into a first data area for the first program loaded into the memory; and
start execution of the second program from a second position on the second program corresponding to a first position where execution of the first program is suspended.

2. The apparatus of claim 1, wherein
the processor is configured to calculate a second offset value of the first data area, whose reference point is a second address assigned to the second program, based on a first offset value of the first data area whose reference point is a first address assigned to the first program.

3. The apparatus of claim 2, wherein
the processor is configured to:
add the second offset value to global offset information for the second program, the global offset information being information in which a symbol name identifying a piece of data to be accessed by the second program is stored in association with an offset value whose reference point is the second address;
acquire the second offset value from the global offset information in response to execution of the second program; and
access to the first data area, based on the acquired second offset value.

4. The apparatus of claim 2, wherein
the processor is configured to calculate the second offset value of each of pieces of data included in the first data area, based on the first offset value of the each piece of data.

5. The apparatus of claim 2, wherein
the processor is configured to:
update global offset information for the first program by adding the first offset value to the global offset table when executing the first program, the global offset information being information in which a symbol name identifying a piece of data to be accessed by the first program is stored in association with an offset value whose reference point is the first address;
when execution of the first program is suspended, store the updated global offset information into a storage; load the first program and the second program into the memory; and
obtain an address of a piece of data of the first data area corresponding to the first offset value by referring to the global offset information stored in the storage.

6. The apparatus of claim 1, wherein
the processor is configured to restore an execution binary image of the first program at the suspension time into the memory by writing the first data at the suspension time into the first data area.

7. The apparatus of claim 1, wherein
the processor is configured to determine whether access destination in the memory for each of plural pieces of data referred to by the second program is the first data area for the first program or a second data area for the second program.

8. The apparatus of claim 1, wherein
the processor is configured to release the second data area arranged in the memory when starting execution of the second program.

9. The apparatus of claim 1, wherein
the processor is configured to:
suspend execution of the first program;
load the first program and the second program into the memory when starting execution of the second program; and
execute the second program without executing the first program by taking over the first data stored in the first data area at the suspension time.

10. A non-transitory, computer-readable recording medium having stored therein a program for causing a computer to execute a process comprising:
causing a program loader to load a first program and a second program that is obtained by correcting the first program, into a memory;
causing a linker to load a library used for execution of the second program into the memory;
writing first data that has been processed at a suspension time at which execution of the first program is suspended, into a first data area for the first program loaded into the memory; and
starting execution of the second program from a second position on the second program corresponding to a first position where execution of the first program is suspended.

11. A method comprising:
causing a program loader to load a first program and a second program that is obtained by correcting the first program, into a memory;
causing a linker to load a library used for execution of the second program into the memory;
writing first data that has been processed at a suspension time at which execution of the first program is suspended, into a first data area for the first program loaded into the memory; and
starting execution of the second program from a second position on the second program corresponding to a first position where execution of the first program is suspended.
